(19) United States
(12) Patent Application Publication
(10) Pub. No.: US 2017/0256324 A1
(43) Pub. Date: Sep. 7, 2017

(54) DEVICE INSPECTION METHOD, PROBE CARD, INTERPOSER, AND INSPECTION APPARATUS

(71) Applicant: TOKYO ELECTRON LIMITED, Tokyo (JP)

(72) Inventors: Tetsuya KAGAMI, Yamanashi (JP); Kanji SUZUKI, Yamanashi (JP)

(21) Appl. No.: 15/501,151

(22) PCT Filed: Jun. 10, 2015
(86) PCT No.: PCT/JP2015/066660

§ 371 Date: Feb. 1, 2017

(30) Foreign Application Priority Data
Aug. 1, 2014 (JP) 2014-157753

(51) Int. Cl. G11C 29/10; G01R 1/073

(52) U.S. Cl. CPC G11C 29/10; G01R 1/07378

(57) ABSTRACT

A signal input/output circuit is provided with an input line, a common output line, a plurality of individual output lines, relay switches, and resistor elements. The common output line is connected to a comparator. The common output line synthesizes response signals transmitted from a plurality of devices under test (DUT), and transmits a synthesized response signal generated by synthesizing, into one signal, the response signals outputted from the respective DUTs. In response to a test signal transmitted from a pattern generator, the comparator compares the synthesized response signal with a threshold value.

### CROSSREFERENCE TO RELATED APPLICATIONS

This application is a National Stage application of, and claims priority to, PCT Application No. PCT/JP2015/066660, filed on Jun. 10, 2015, entitled “DEVICE INSPECTION METHOD, PROBE CARD, INTERPOSER, AND INSPECTION APPARATUS,” which claims priority to Japanese Patent Application No. 2014-157753, filed on Aug. 1, 2014. The foregoing patent applications are herein incorporated by reference by entirety for all purposes.

### FIELD OF THE INVENTION

The present invention relates to a device inspection method for inspecting electrical characteristics of a device, a probe card used therefor, an interposer, and an inspection apparatus.

### BACKGROUND OF THE INVENTION

Electrical characteristics of devices such as an integrated circuit formed on a semiconductor wafer (hereinafter, referred to as “wafer”), a semiconductor memory or the like are inspected by using an inspection apparatus having a probe card. The probe card has a plurality of probes (contactors) made to be in contact with electrode pads of the devices on the wafer. An electronic circuit on the wafer is inspected by transmitting an electrical signal to the respective probes from a tester in a state where the respective probes are made to be in contact with the electrode pads on the wafer.

Recently, along with a trend toward miniaturization of an electronic circuit pattern and scaling up of a wafer, the number of devices formed on a single wafer is considerably increasing. Therefore, a method in which a plurality of devices to be inspected (hereinafter, referred to as “DUT”) is connected to a single tester and sequentially inspected is disadvantageous in that a long period of time is required until the inspection for all DUTs is completed.

In Japanese Patent Application Publication No. H4-158275 (Patent Document 1), there is suggested a method in which all DUTs are determined as PASS when a sum B of simultaneously measured leakage currents of two or more DUTs connected in parallel to a tester is smaller than a reference value A (A>B). In that method, when A is smaller than B (A<B), at least one of the DUTs is determined as FAIL and, then, a leakage current of each of DUTs is measured individually. In the inspection method of Patent Document 1, the sum B of the leakage currents is used as an index. Since, however, the leakage current value varies depending on the DUTs, the number of poor DUTs cannot be estimated when the simultaneous measurement result satisfies the relation A<B.

### SUMMARY OF THE INVENTION

In view of the above, the present invention provides an inspection method capable of effectively inspecting electrical characteristics of a plurality of devices within a short period of time.

In accordance with an aspect, there is provided a device inspection method for inspecting electrical characteristics of a plurality of devices formed on a substrate, the method including: a first step of simultaneously inputting test signals from a tester to the respective devices connected in parallel to the tester; and a second step of determining whether or not one or more of the devices are FAIL based on a synthesized value of response signals from the respective devices based on the inputted test signals.

In the second step, the synthesized value may be compared with a preset threshold value and it is determined that one or more of the devices are FAIL when the synthesized value does not satisfy the threshold value. In this case, the method may further include setting a new threshold value different from the threshold value when the synthesized value does not satisfy the threshold value in the second step, and the first step and the second step may be executed again by using the new threshold value.

The number of devices that are determined as FAIL may be detected by repeating the setting a new threshold value, the first step and the second step until the synthesized value satisfies the new threshold value.

The threshold value is set in multiple steps and a threshold value TH_{N} set in N^{th} determination and a threshold value TH_{N+1} set in N+1^{th} determination satisfy relation TH_{N}>TH_{N+1} (N being a positive integer of 1 or more). Here, when the devices are an n-number of devices (n being a positive integer of 2 or more) and the synthesized value of the response signals obtained when all the n-number of devices are determined as PASS is indicated by S₀, the threshold value TH_{N} may satisfy a following relation:

S₀×[n−(N−1)]/n≧TH_{N}>S₀×(n−N)/n.

The device may be a non-volatile semiconductor memory, and the first step and the second step may be executed as a write test of the non-volatile semiconductor memory.

In accordance with another aspect, there is provided a probe card which is provided between a tester for inspecting electrical characteristics of a plurality of devices formed on a substrate and the substrate, the probe card including: a plurality of probes to be brought into contact with respective electrode pads of the devices, and a base plate configured to hold the probes. The base plate includes: an input line connected to the respective probes and configured to transfer test signals from the tester to the respective devices; a plurality of individual output lines connected to the respective probes and configured to transfer response signals from the respective devices based on the test signals; and a common output line configured to combine the individual output lines, synthesize the response signals from the respective devices, and transmit a synthesized signal toward the tester, wherein the respective individual output lines are provided with resistors having resistances greater than internal resistances of the respective devices.

Each of the individual output line may be further provided with a relay switch unit connected in series to the resistor.

In accordance with still another aspect, there is provided an interposer which is provided between a tester for inspecting electrical characteristic of a plurality of devices formed on a substrate and the substrate, the interposer including: an input line configured to transmit test signals from the tester toward the respective devices; a plurality of individual output lines configured to transmit response signals from the respective devices based on the test signals; and a common output line configured to combine the respective individual output lines, synthesize the response signals from the respective devices, and transmit a synthesized signal toward the tester, wherein the respective individual output lines are provided with resistors having resistances greater than internal resistances of the respective devices.

In the interposer, each of the individual output lines may be further provided with a relay switch unit connected in series to the resistor.

In accordance with another aspect, there is provided an inspection apparatus for inspecting electrical characteristics of a plurality of devices formed on a substrate, the apparatus including: a pattern generator configured to generate test signals for inspecting the respective devices; a comparator configured to compare a synthesized response signal of response signals from the respective devices based on the test signals with a threshold value; and a signal input/output circuit provided between the pattern generator and the comparator, and the devices, wherein the signal input/output circuit includes: an input line configured to transmit the test signals toward the respective devices; a plurality of individual output lines configured to transmit response signals from the respective devices based on the test signals; and a common output line configured to combine the respective individual output lines, synthesize the response signals from the respective devices, and transmit a synthesized signal toward the tester, and wherein the respective individual output lines are provided with resistors having resistances greater than internal resistances of the respective devices.

In the inspection apparatus, each of the individual output lines may be further provided with a relay switch unit connected in series to the resistor. In addition, the inspection apparatus may further include a controller including: a signal control unit configured to control generation of the test signals by the pattern generator; a determination unit configured to determine whether or not one or more of the devices are FAIL based on comparison information between the threshold value and the synthesized response signal, which is obtained by the comparator; and a threshold setting unit configured to set a new threshold value different from the threshold value when one or more of the devices are determined as FAIL by the determination unit.

### BRIEF DESCRIPTION OF THE DRAWINGS

FIG. 1 is a cross sectional view showing a schematic configuration of an inspection apparatus according to an embodiment.

FIG. 2 is a schematic diagram showing an example of a single input/output circuit in an embodiment.

FIG. 3 shows an example of a hardware configuration of a control unit shown in FIG. 1 FIG. 4 is a functional block diagram of the control unit shown in FIG. 1.

FIG. 5 explains a test signal, a response signal and a threshold value in a conventional inspection method.

FIGS. 6A to 6C are views for explaining a magnitude of a synthesized response signal obtained by an inspection method according to an embodiment.

FIG. 7 explains exemplary setting of a threshold value for the synthesized response signal in the inspection method according to the embodiment.

FIG. 8 is a flowchart showing an exemplary sequence of the inspection method according to the embodiment.

### DETAILED DESCRIPTION OF THE EMBODIMENTS

(Inspection Apparatus)

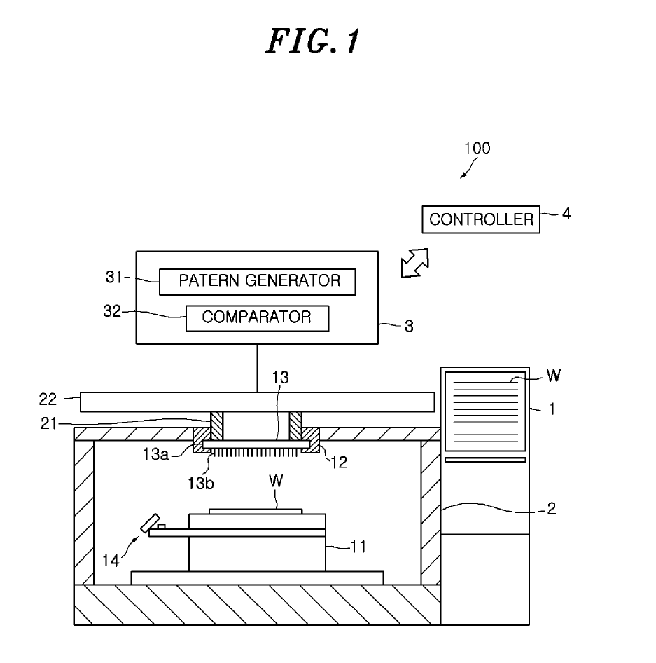

FIG. 1 is a cross sectional view showing a schematic configuration of an inspection apparatus according to an embodiment. In FIG. 1, an inspection apparatus 100 includes a loader chamber 1, an inspection chamber 2 accommodating a wafer W on which a plurality of devices to be inspected (DUT) (not shown in FIG. 1) is formed, a tester 3 for inspecting electrical characteristics of the DUTs 10 on the wafer W, and a control unit 4 for controlling the respective components of the inspection apparatus 100.

(Loader Chamber)

The loader chamber 1 forms a transfer region for transferring the wafer W.

(Inspection Chamber)

The inspection chamber 2 includes a mounting table 11 for mounting thereon the wafer W, and a holder 12 provided above the mounting table 11. The mounting table 11 is configured to move the wafer W mounted thereon in X, Y, Z and θ directions. The holder 12 holds the probe card 13. The probe card 13 has a base plate 13a and a plurality of probes (contactors) 13b. The probe card 13 is electrically connected to the tester 3 via a connection ring 21 having a plurality of connection terminals, an interposer (or performance board) 22, and a test head (not shown).

The inspection chamber 2 further includes an alignment mechanism 14 for performing alignment between the respective probes 13b of the probe card 13 held by the holder 12 and electrode pads (not shown) of the DUTs 10 formed on the wafer W mounted on the mounting table 11.

(Tester)

The tester 3 transmits electrical signals to the DUTs and receives response signals from the DUTs 10, thereby inspecting electrical characteristics of the DUTs 10 on the wafer W. The tester 3 includes a pattern generator 31 and a comparator 32.

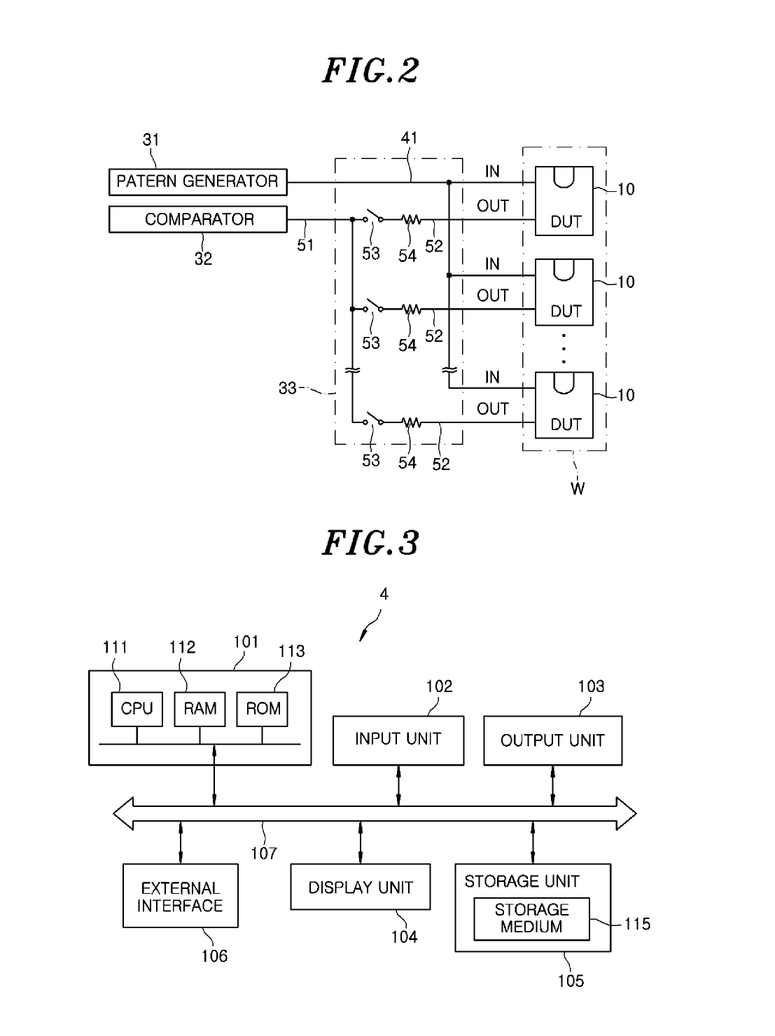

FIG. 2 is a schematic diagram showing an example of a signal input/output circuit 33 for electrically connecting the pattern generator 31 and the comparator 32 with the DUTs 10.

The pattern generator 31 generates test signals for inspecting the DUTs 10. The pattern generator 31 and the DUTs 10 are connected by an input line 41 that is a wiring branched into a plurality of lines.

The comparator 32 compares response signals outputted from the DUTs 10 or a synthesized signal of the response signals from the DUTs 10 (hereinafter, referred to as “synthesized response signal”) with a threshold in response to the test signals from the pattern generator 31. The comparator 32 is connected to a common output line 51 that is a wiring for synthesizing and transmitting the responsive signals from the DUTs 10. The comparator 32 and the DUTs 10 are connected by the common output line 51 and individual output lines 52 that are wirings from the DUTs 10.

(Signal Input/Output Circuit)

As shown in FIG. 2, the signal input/output circuit 33 includes the input line 41, the common output line 51, the individual output lines 52, relay switches 53, resistor elements 54. In the present embodiment, the signal input/output circuit 33 may be mounted on any one of the tester 3, the base plate 13a of the probe card 13, and the interposer (or performance board) 22.

The input line 41 is branched into a plurality of lines of which number is determined by the number of the DUTs 10 to be inspected at the same time. The pattern generator 31 and the DUTs 10 are connected in parallel by the input line 41. The test signals generated by the pattern generator 31 are transmitted to the DUTs 10 through the input line 41. The input line 41 may be provided with a relay switch unit for switching connection/disconnection between the pattern generator 31 and the DUTs 10, or the like. Further, the configuration of the input line 41 is not limited to the configuration shown in FIG. 2 as long as the test signals can be simultaneously transmitted to the DUTs 10.

The common output line 51 includes a plurality of individual output line 52 for transmitting response signals from the DUTs 10 based on the test signals inputted from the pattern generator 31. The response signals outputted from the DUTs 10 are transmitted to the comparator 32 through the individual output lines 52 and the common output line 51.

In each of the individual output lines 52, the relay switch 53 and the resistor element 54 are provided in series. The arrangement order of the relay switch 53 and the resistor element 54 is not limited.

The relay switches 53 can be used in the case of switching connection/disconnection between the comparator 32 and the DUTs 10. When the response signals from the DUTs 10 are synthesized to one, all the relay switch units 53 may be set to a connection state (ON). When the response signals from the DUTs 10 are individually transmitted to the comparator 32, the relay switch 53 of only one of the individual output lines 52 may be set to the connection state (ON) and the relay switches 53 of the other individual output lines 52 may be set to a disconnection state (OFF). When it is not necessary to transmit the response signals from the DUTs 10 to the comparator 30 individually, the relay switches 53 may not be provided.

The resistor element 54 functions to select a response signal and has a resistance greater than internal resistance (output impedance) of each of the DUTs 10 to control an impedance in the common output line 51 connected to the respective individual output lines 52.

(Controller)

The respective components of the inspection apparatus 100 are connected to and controlled by the controller 4. The controller 4 is typically a computer. FIG. 3 shows an example of a hardware configuration of the controller 4 shown in FIG. 1. The controller 4 includes a main controller 101, an input unit 102 such as a keyboard, a mouse or the like, an output unit 103 such as a printer or the like, a display unit 104, a storage unit 105, an external interface 106, and a bus 107 that connects these components. The main controller 101 has a CPU (central processing unit) 111, a RAM (random access memory) 112, and a ROM (read only memory) 113. The storage unit 105 may be any storage unit as long as it can store information. For example, the storage unit 105 is a hard disk device or an optical disk device. The storage unit 105 is configured to store information in a computer-readable storage medium 115 and read out information from the storage medium 115. The storage medium 115 may be any storage medium as long as it can store information. For example, the storage medium 115 is a hard disk, an optical disk, a flash memory or the like. The storage medium 115 may be a storage medium in which a recipe of the inspection method of the present embodiment is stored.

In the controller 4, the CPU 111 executes a program stored in the ROM 113 or in the storage unit 105 while using the RAM 112 as a work area. Accordingly, the inspection of the DUTs 10 formed on the wafer W in the inspection apparatus 100 of the present embodiment can be performed. Specifically, the controller 4 controls the respective components of the inspection apparatus 100 (e.g., the mounting table 11, the alignment mechanism 14, the pattern generator 31, the comparator 32, the relay switch units 53 and the like).

FIG. 4 is a functional block diagram of the controller 4 and shows relation between the pattern generator 31 and the comparator 32 of the tester 3. As shown in FIG. 4, the controller 4 includes a signal control unit 121, a determination unit 122, and a threshold setting unit 123. These components are realized by allowing the CPU 111 to execute software (program) stored in the ROM 113 or in the storage unit 105 while using the RAM 112 as a work area. Further, the probe card 13 or the interposer (or the performance board) 22 may have the same functions as those of the signal control unit 121, the determination unit 122 and the threshold setting unit 123 by using, e.g., FPGA (field programmable gate array) or the like. The controller has other functions (e.g., a function of controlling connection/disconnection of the relay switch 53 and the like). However, detailed description thereof will be omitted.

The signal control unit 121 controls generation of test signals by the pattern generator 31. Specifically, the signal control unit 121 transmits control signals to the pattern generator 31 and instructs types and start/stop of generation of clock signals and data signals generated by the pattern generator 31.

The determination unit 122 obtains comparison information between the threshold value and the response signals from the comparator 32. Based on the comparison information, the determination unit 122 determines whether or not one or more DUTs 10 are FAIL, i.e., whether or not all the DUTs 10 are PASS. The determination operation may be performed by the comparator 32 instead of the determination unit 122. The determination unit 122 can determine the number of DUTs 10 that have outputted FAIL signals among the DUTs 10 based on the following sequence.

The threshold setting unit 123 sets a threshold value used for the comparator 32 to perform comparison. The threshold setting unit 123 can set a plurality of thresholds in multiple steps, and the threshold values may be dynamically changed. For example, when one or more DUTs 10 are determined as FAIL by the determination unit 122 (or the comparator 32) from the comparison information between a first threshold value and the synthesized response signal, the threshold setting unit 123 can set, as a new threshold, a second threshold different from the first threshold.

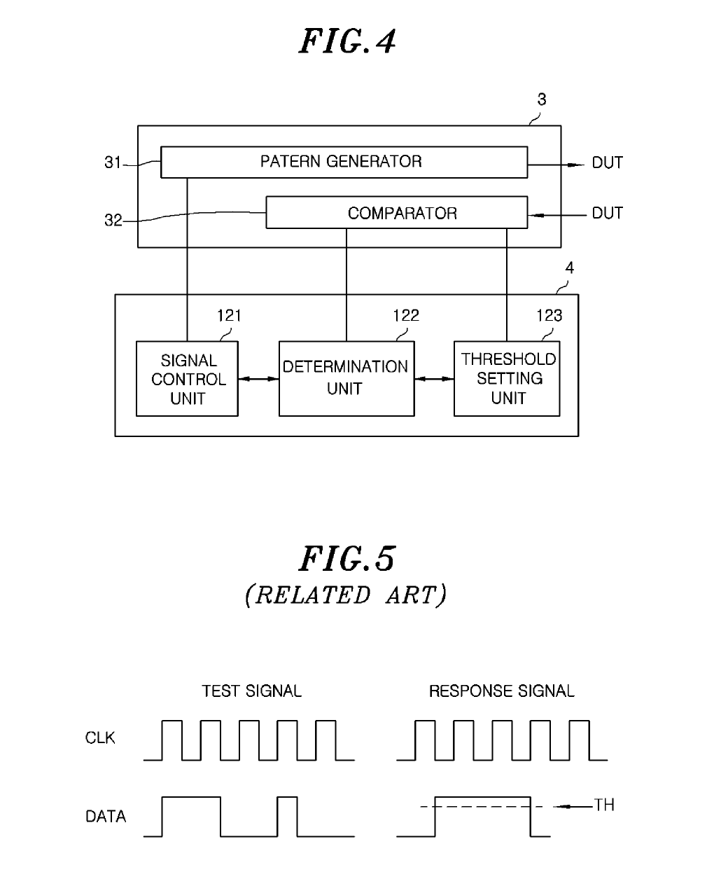

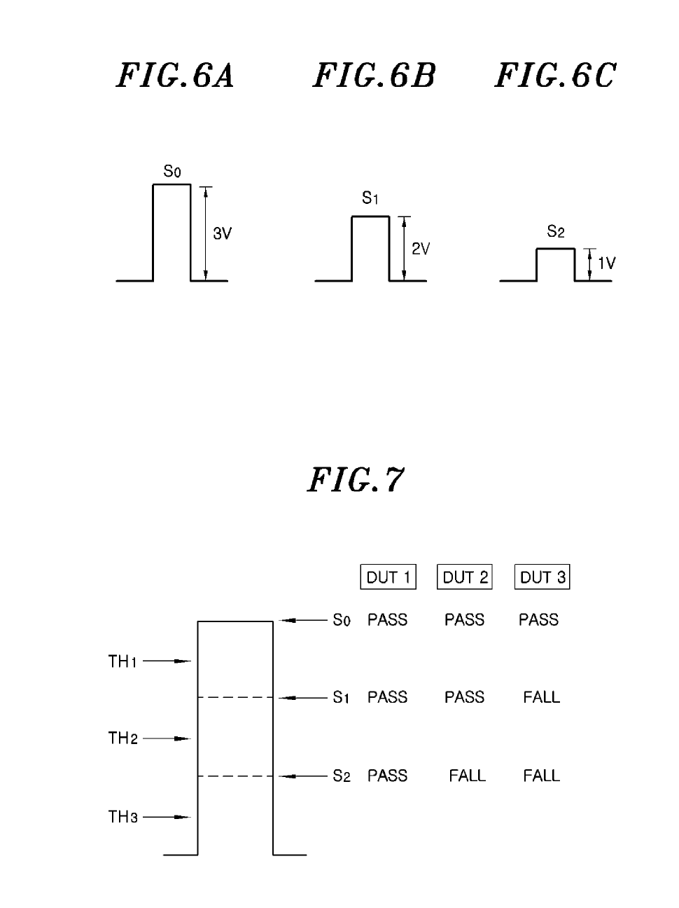

Hereinafter, a threshold value setting method in the threshold setting unit 123 will be described with reference to FIGS. 5 and 6. FIG. 5 explains a test signal, a response signal, and a threshold value in a conventional inspection method. The pattern generator 31 generates a clock signal CLK and a data signal DATA. These signals are inputted as test signals into the DUTs 10. As a result, the response signals are outputted from the DUTs 10 and PASS/FAIL of the DUTs 10 are determined by the comparator 32 based on the levels of the response signals. For example, if a threshold value TH for the comparison in the comparator 32 is 3V, a response signal greater than or equal to 3V is determined as PASS and a response signal lower than 3V is determined as FAIL. The individual response signals from the DUTs 10 may include a PASS signal that satisfies the threshold value TH and a FAIL signal that does not satisfy the threshold value TH. Therefore, a synthesized response signal may include only PASS signals, or only FAIL signals, or both of the PASS signals and the FAIL signals.

FIGS. 6A to 6C show magnitudes (e.g., voltage levels) of synthesized response signals obtained by the inspection method of the present embodiment. FIG. 7 explains an exemplary setting of threshold values for the synthesized response signals in the inspection method of the present embodiment. In FIGS. 6A to 6C and 7, for example, three DUTs 10 are provided. The signals inputted from the pattern generator 31 to the DUTs 10 have the same level and the same pattern. The individual response signals from the DUTs 10 may include the PASS signal and the FAIL signal as described above. In cases where the response signals include only the PASS signals and both of the PASS signals and the FAIL signals, there are obtained synthesized response signals of different values.

For example, when the individual response signals of the DUTs 10 have two output levels, i.e., Hi(PASS): 3[V] and Low(FAIL): 0[V], if output levels S_{D} of the individual response signals of all the three DUTs 10 are Hi, an output level S₀ of the synthesized response signal becomes 3[V] as shown in FIG. 6A.

When the output levels S_{D} of the individual response signals of two DUTs 10 among the three DUTs 10 are Hi and the output level S_{D} of the individual response signal of one DUT 10 is Low, an output level S₁ of a synthesized response signal becomes 2[V][=3[V]×(3−1)/3] as shown in FIG. 6B.

When the output level S_{D} of the individual response signal of one of the three DUTs 10 is Hi and the output levels S_{D} of the individual response signals of the other two DUTs 10 are Low, an output level S₂ of the synthesized response signal becomes 1[V][=3[V]×(3−2)/3] as shown in FIG. 6C. Each of the DUTs 10 has two output impedances, i.e., Hi of 3 [V] and Low of 0[V].

In other words, all of the n-number of DUTs 10 output PASS signals of the same output level S_{D}[V], the output level S₀ of the synthesized response signal becomes S₀[V]=S_{D}[V]×n/n. When one of the n-number of DUTs 10 outputs a FAIL signal and the other DUTs 10 output PASS signals, the output level S₁ of the synthesized response signal becomes S₁[V]=S_{D}[V]×(n−1)/n. When two of the n-number of DUTs 10 output FAIL signals and the other DUTs 10 output PASS signals, the output level S₂ of the synthesized response signal becomes S₂[V]=S_{D}[V]×(n−2)/n.

In the inspection method of the present embodiment, it is preferable to sequentially compare the output levels of the synthesized response signals with the threshold values TH₁, TH₂, TH₃, . . . by the comparator 32. When the output level of the synthesized response signal satisfies the threshold value TH, the determination unit 122 determines that “all DUTs 10 are PASS”. When the output level of the synthesized response signal does not satisfy the threshold value TH, the determination unit 122 determines that “one or more DUTs 10 are FAIL”.

As shown in FIG. 7, in the first determination, the threshold value TH₁ may be set between the output level S₀ of the synthesized response signal obtained when all the three DUTs 10 are PASS and the output level S₁ of the synthesized response signal obtained when one DUT 10 is FAIL. Accordingly, when the output level of the synthesized response signal is greater than or equal to the threshold value TH₁, all the DUTs 10 are determined as PASS. When the output level of the synthesized response signal is smaller than the threshold value TH₁, one or more DUTs 10 are determined as FAIL.

In the second determination, the threshold value TH₂ may be set between the output level S₁ of the synthesized response signal obtained when one DUT 10 is FAIL and the output level S₂ of the synthesized response signal obtained when two DUTs 10 are FAIL. Accordingly, in combination with the first determination result, when the output level of the synthesized response signal is greater than or equal to the threshold value TH₂, two DUTs 10 are determined as PASS and one DUT 10 is determined as FAIL. When the output level of the synthesized response signal is smaller than the threshold value TH₂, two or more DUTs 10 are determined as FAIL.

In the third determination, the threshold value TH₃ may be set to be lower than the output level S₂ of the synthesized response signal obtained when two DUTs 10 are FAIL. Accordingly, in combination with the first and the second determination result, when the output level of the synthesized response signal is greater than or equal to the threshold value TH₃, it is determined that one DUT 10 is determined as PASS and two DUTs 10 are determined as FAIL. When the output level of the synthesized response signal is smaller than the threshold value TH₃, three DUTs 10 are determined as FAIL.

In the case of performing the determination for the n-number of DUTs 10 (n being a positive integer of 2 or more) while decreasing the threshold value by one level, on the assumption that a threshold value set for N^{th} determination (N being a positive integer of 1 or more) is TH_{N} and a threshold value set for N+1^{th} determination is TH_{N+1}, relation TH_{N}>TH_{N+1} is satisfied. Further, a threshold value TH_{N} set for the N^{th} determination for the output level of the synthesized response signal obtained when all the n-number of DUTs 10 are PASS preferably satisfies relation of the following Eq. (1).

S₀×[n−(N−1)]/n≧TH_{N}>S₀×(n−N)/n Eq. (1)

It is more preferable to set the threshold value TH_{N} to be close to an intermediate value between S₀×[n−(N−1)]/n and S₀×(n−N)/n in order to improve reliability of determination in consideration of a margin. In other words, when the synthesized response signals obtained in the case of increasing the number of DUTs 10 that output FAIL signals by one from 0 are indicated by S₀, S₁, S₂, . . . , Sₙ, the threshold value TH_{N} is preferably set to be close to an intermediate value between S₀ and S₁, an intermediate value between S₁ and S₂, . . . and an intermediate value between Sₙ₋₁ and Sₙ. In that case, the threshold value TH_{N} is preferably obtained by the following Eq. (2).

TH_{N}=[{S₀×[n−(N−1)]/n}+{S₀×(n−N)/n}]×½ Eq. (2)

(Inspection Method)

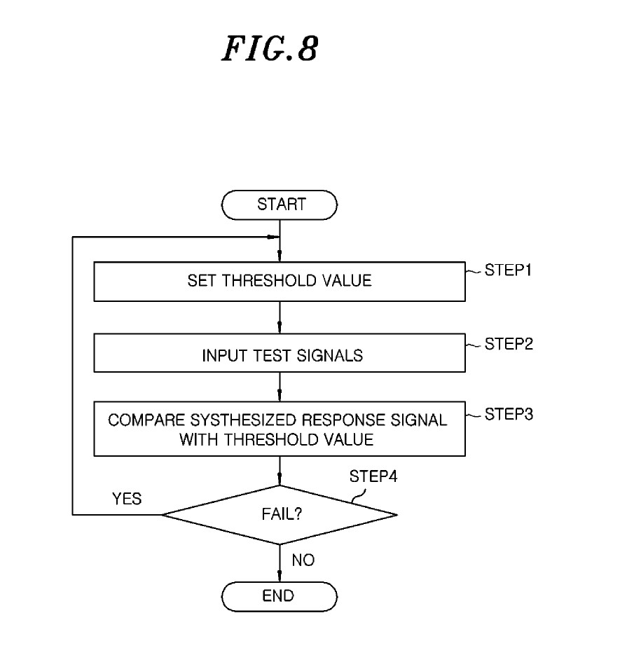

Next, a specific sequence of an inspection method according to an embodiment which is performed by using the inspection apparatus 100 will be described with reference to FIG. 8. FIG. 8 is a flowchart showing an example of the sequence of the inspection method according to an embodiment. The inspection method of the present embodiment includes steps STEP1 to STEP4.

In the step STEP1, the threshold value TH₁ used for the first determination is set. The threshold value TH₁ is set by the threshold setting unit 123. According to the above Eq. (1), the threshold value TH₁ set in the first determination with respect to the output level S₀ of the synthesized response signal obtained when all the n-number of DUTs 10 are PASS preferably satisfies the following relation.

S₀×n/n≧TH₁>S₀×(n−1)/n

In consideration of the margin, it is more preferable that the threshold value TH₁ is obtained by the following equation.

TH₁=[S₀×n/n+S₀×(n−1)/n]×½.

In the step STEP2, the clock signal and the data signal are generated by the pattern generator 31 based on the instruction of the signal control unit 121. Then, the same test signal is inputted to all the n-number of DUTs 10.

In the step STEP3, a synthesized value (synthesized response signal) of the response signals outputted from the DUTs 10 in response to the test signal are compared with the threshold value TH₁ by the comparator 322. In that case, the relay switch units 53 are maintained at the connection state (ON).

Next, in the step STEP4, the determination unit 122 obtains the comparison information between the threshold value TH₁ and the synthesized response signal from the comparator 32 and determines, based on the comparison information, whether or not one or more DUTs 10 among the n-number of DUTs 10 are FAIL, i.e., whether or not all the DUTs 10 are PASS.

When it is determined in the step STEP4 that one or more DUTs 10 among the n-number of DUTs 10 are FAIL (YES), the process returns to the step STEP1. In other words, in the step STEP1, the threshold value TH₂ used in the second determination is set as a new threshold value by the threshold value setting unit 123. According to the above Eq. (1), the threshold value TH₂ set in the second determination with respect to the output level S₀ of the synthesized response signal obtained when all the n-number of DUTs 10 are PASS preferably satisfies the following relation.

S₀×(n−1)/n≧TH₂>S₀×(n−2)/n

In consideration of the margin, it is more preferable that the threshold value TH₂ is obtained by the following equation.

TH₂={[S₀×(n−1)/n]+[S₀×(n−2)/n]}×½

When the new threshold value (e.g., the threshold value TH₂ used in second determination) is set in the step STEP1, the second determination is performed by executing the steps STEP2 to STEP4. In this manner, the STEP 1 to 4 are repeated in a loop until it is determined in the step STEP4 that none of the n-number of DUTs 10 is FAIL (NO). When the number of repetition reaches an upper limit that has been set in advance, a stop signal may be transmitted from the determination unit 122 to the signal control unit 121 and the threshold value setting unit 123.

On the other hand, when it is determined in the step STEP4 that none of the n-number of DUTs 10 is FAIL (NO), the process of the inspection method of the present embodiment is completed.

In the present embodiment, the number of DUTs 10 that have outputted FAIL signals among the n-number of DUTs 10 can be determined by changing the threshold value TH in response to the output levels S₀, S₁, S₂, . . . , S_{N} (N being a positive integer of 1 or more) of the synthesized response signals obtained in the case of increasing the number of DUTs 10 that output FAIL signals by one from 0.

In other words, in the first determination, the threshold value TH₁ is set between the output level S₀ of the synthesized response signal obtained when all the n-number of DUTs 10 output PASS signals (i.e., FAIL signal is not outputted from any of the DUTs 10) and the output level S₁ of the synthesized response signal obtained when one of the n-number of DUTs 10 outputs a FAIL signal (preferably close to the intermediate value between the output level S₀ and the output level S₁).

In the second determination, the threshold value TH₂ is set between the output level S₁ of the synthesized response signal obtained when one of the n-number of DUTs 10 outputs a FAIL signal and the output level S₂ of the synthesized response signal obtained when two of the n-number of DUTs 10 output FAIL signals (preferably close to the intermediate value between the output level S₁ and the output level S₂).

In the N^{th} determination, the threshold value TH_{N} is set between the output level S_{(N-1)} of the synthesized response signal obtained when the N−1 number of DUTs 10 among the n-number of DUTs 10 output FAIL signals and the output level S_{N} of the synthesized response signal obtained when the N-number of DUTs 10 among the n-number of DUTs 10 output FAIL signals (preferably close to the intermediate value between the output level S_{(N-1)} and the output level S_{N}). In this manner, the number of DUTs 10 that have outputted FAIL signals among the n-number of DUTs 10 can be automatically determined by repeating the step STEP1 to STEP4 while varying the threshold value TH.

In the case of repeating the steps STEP1 to STEP4, it is possible to increase a count value by one whenever the threshold value TH is set by the threshold value setting unit 123. In that case, the count value (1, 2, 3, . . . , N) counted by a counter unit (not shown) that is provided in the controller 4 and connected to the threshold value setting unit 123 becomes the same as the number of execution of the steps STEP1 to STEP4. The count value (1, 2, 3, . . . , N) obtained when it is finally determined in the step STEP4 that none of the n-number of DUTs 10 is FAIL (NO) is greater by one than the number of DUTs 10 that have outputted FAIL signals. Therefore, the number of DUTs 10 that have outputted FAIL signals can be quickly obtained.

When the output levels S_{D} of the individual response signals from the DUTs 10 may vary, there may be provided a step of measuring in advance the output levels S_{D} of the individual response signals from one or several DUTs 10 and correcting the threshold value TH set by the threshold value setting unit 123 based on the measured values.

(Modification)

In the inspection method of the present embodiment, it is not possible to specify a DUT 10 that has outputted a FAIL signal, as described above. Therefore, a step of comparing the output levels S_{D} of the individual response signals from the DUTs with the threshold value TH may be provided in addition to the steps STEP1 to STEP4. In other word, when it is determined in the step STEP4 that one or more DUTs 10 among the n-number of DUTs 10 are FAIL (YES), the output levels S_{D} of the individual response signals from the DUTs 10 may be compared with the threshold value TH without returning to the step STEP1. In that case, the individual response signals may be transmitted to the comparator 32 while setting the relay switch unit 43 of one of the individual output lines 52 of the signal input/output circuit 33 to the connection state (ON) and the relay switch units 43 of the other individual output lines 52 to the disconnection state (OFF). Instead of switching the relay switch unit 53, there may be used a chip select terminal that can be electrically connected to a DUT selected among the DUTs 10. When it is determined in the step STEP4 of the first sequence that “one or more DUTs 10 among the n-number of DUTs 10 are FAIL” (YES), the process may immediately proceed to the determination of the individual response signals. Or, the process may proceed to the determination of the individual response signals only when it is determined in the step STEP4 that “one or more DUTs 10 among the n-number of DUTs 10 are FAIL” (YES) after the steps STEP1 to STEP4 are repeated a predetermined number of times (e.g., five to ten times).

As described above, in the inspection method of the present embodiment, the comparison with the threshold value TH is performed by using the synthesized response signal obtained by synthesizing the output signals from the DUTs 10, so that it is possible to quickly determine whether or not a FAIL DUT 10 is included in the DUTs 10. By repeating the steps STEP1 to STEP4 while varying the threshold value TH, the number of DUTs 10 that have outputted FAIL signals among the n-number of DUTs 10 can be automatically determined. Therefore, the inspection method of the present embodiment enables various semiconductor devices to be inspected effectively within a short period of time.

The inspection method of the present embodiment may be used for inspection of various semiconductor devices. Especially, the inspection method of the present embodiment is preferably used for a write test of a non-volatile semiconductor memory device, e.g., a NAND-type flash memory or the like. In the inspection method of the present embodiment, although the number of DUTs 10 that have outputted FAIL signals can be automatically and quickly determined, it is not possible to specify the DUTs 10 that have outputted the FAIL signals as described above. However, in the case of the non-volatile semiconductor memory device, a read test is performed on each of the DUTs 10 after the write test and, thus, it is possible to determine PASS/FAIL of the DUTs 10 and specify the FAIL DUTs 10 by the read test.

While the embodiment of the present invention has been described in detail, the present invention may be variously modified without being limited to the above embodiment. For example, the inspection method of the present invention may be preferably used regardless of types of devices as long as devices that output READY signal/BUSY signal are inspected collectively.

In the flowchart of FIG. 8, whenever the processes from the steps STEP2 to STEP4 are performed once, a new threshold is set in the STEP1. However, even in the case of repeating the processes from the steps STEP2 to STEP4 a predetermined number of times, the process may return to the step STEP1 when it is determined in the step STEP4 that “one or more DUTs 10 among the n-number of DUTs 10 are FAIL” (YES) to set a new threshold value.

This application claims priority to Japanese Patent Application No. 2014-157753 filed on Aug. 1, 2014, the entire contents of which are incorporated herein by reference.

What is claimed is:

1. A device inspection method for inspecting electrical characteristics of a plurality of devices formed on a substrate, comprising:
a first step of simultaneously inputting test signals from a tester to the respective devices connected in parallel to the tester; and
a second step of determining whether or not one or more of the devices are FAIL based on a synthesized value of response signals from the respective devices based on the inputted test signals.

2. The device inspection method of claim 1, wherein in the second step, the synthesized value is compared with a preset threshold value and it is determined that one or more of the devices are FAIL when the synthesized value does not satisfy the threshold value, and the method further comprises:
setting a new threshold value different from the threshold value when the synthesized value does not satisfy the threshold value in the second step, and
wherein the first step and the second step are executed again by using the new threshold value.

3. The device inspection method of claim 2, wherein the number of devices that are determined as FAIL is detected by repeating the setting a new threshold value, the first step and the second step until the synthesized value satisfies the new threshold value.

4. The device inspection method of claim 3, wherein the threshold value is set in multiple steps and a threshold value TH_{N} set in N^{th} determination and a threshold value TH_{N+1} set in N+1^{th} determination satisfy relation TH_{N}>TH_{N+1}, where N is a positive integer of 1 or more, and
wherein, when the devices are an n-number of devices where n is a positive integer of 2 or more and the synthesized value of the response signals obtained when all the n-number of devices are determined as PASS is indicated by S₀, the threshold value TH_{N} satisfies a following relation:
S₀×[n−(N−1)]/n≧TH_{N}>S₀×(n−N)/n.

5. The device inspection method of claim 1, wherein the device is a non-volatile semiconductor memory, and the first step and the second step are executed as a write test of the non-volatile semiconductor memory.

6. A probe card which is provided between a tester for inspecting electrical characteristics of a plurality of devices formed on a substrate and the substrate, the probe card comprising:
a plurality of probes to be brought into contact with respective electrode pads of the devices, and
a base plate configured to hold the probes,
wherein the base plate includes:
an input line connected to the respective probes and configured to transfer test signals from the tester to the respective devices;
a plurality of individual output lines connected to the respective probes and configured to transfer response signals from the respective devices based on the test signals; and
a common output line configured to combine the individual output lines, synthesize the response signals from the respective devices, and transmit a synthesized signal toward the tester,
wherein the respective individual output lines are provided with resistors having resistances greater than internal resistances of the respective devices.

7. The probe card of claim 6, wherein each of the individual output line is further provided with a relay switch unit connected in series to the resistor.

8. An interposer which is provided between a tester for inspecting electrical characteristic of a plurality of devices formed on a substrate and the substrate, the interposer comprising:
an input line configured to transmit test signals from the tester toward the respective devices;
a plurality of individual output lines configured to transmit response signals from the respective devices based on the test signals; and
a common output line configured to combine the respective individual output lines, synthesize the response signals from the respective devices, and transmit a synthesized signal toward the tester,
wherein the respective individual output lines are provided with resistors having resistances greater than internal resistances of the respective devices.

9. The interposer of claim 8, wherein each of the individual output lines is further provided with a relay switch unit connected in series to the resistor.

10. An inspection apparatus for inspecting electrical characteristics of a plurality of devices formed on a substrate, comprising:
a pattern generator configured to generate test signals for inspecting the respective devices;
a comparator configured to compare a synthesized response signal of response signals from the respective devices based on the test signals with a threshold value; and
a signal input/output circuit provided between the pattern generator and the comparator, and the devices,
wherein the signal input/output circuit includes:
an input line configured to transmit the test signals toward the respective devices;
a plurality of individual output lines configured to transmit response signals from the respective devices based on the test signals; and
a common output line configured to combine the respective individual output lines, synthesize the response signals from the respective devices, and transmit a synthesized signal toward the tester, and
wherein the respective individual output lines are provided with resistors having resistances greater than internal resistances of the respective devices.

11. The inspection apparatus of claim 10, wherein each of the individual output lines is further provided with a relay switch unit connected in series to the resistor.

12. The inspection apparatus of claim 10, further comprising a controller including:
a signal control unit configured to control generation of the test signals by the pattern generator;
a determination unit configured to determine whether or not one or more of the devices are FAIL based on comparison information between the threshold value and the synthesized response signal, which is obtained by the comparator; and
a threshold setting unit configured to set a new threshold value different from the threshold value when one or more of the devices are determined as FAIL by the determination unit.
